(19) United States
(12) Patent Application Publication
(10) Pub. No.: US 2024/0047584 A1
(43) Pub. Date: Feb. 8, 2024

(54) THIN-FILM TRANSISTOR AND METHOD FOR MANUFACTURING THE SAME

(71) Applicants: CHUNGANG UNIVERSITY INDUSTRY ACADEMIC COOPERATION FOUNDATION, Seoul (KR); RESEARCH & BUSINESS FOUNDATION SUNGKYUNKWAN UNIVERSITY, Suwon-si (KR)

(72) Inventors: Sung Kyu PARK, Seoul (KR); Seong Pil JEON, Anyang-si (KR); Yong-Hoon KIM, Seongnam-si (KR); Bo Yeon PARK, Suwon-si (KR)

(73) Assignees: CHUNGANG UNIVERSITY INDUSTRY ACADEMIC COOPERATION FOUNDATION, Seoul (KR); RESEARCH & BUSINESS FOUNDATION SUNGKYUNKWAN UNIVERSITY, Suwon-si (KR)

(21) Appl. No.: 18/349,432

(22) Filed: Jul. 10, 2023

(30) Foreign Application Priority Data
Aug. 5, 2022 (KR) 10-2022-0097845

(51) Int. Cl. H01L 29/786; H01L 29/66; H01L 29/417

(52) U.S. Cl. CPC H01L 29/78693; H01L 29/6675; H01L 29/41733

(57) ABSTRACT

Disclosed are a thin-film transistor and a method for manufacturing the same. The thin-film transistor includes: a substrate serving as a gate electrode; a gate insulating film formed on the substrate; a metal layer formed on the gate insulating film; a metal oxide layer formed on the metal layer and covering an entirety of a surface of the metal layer; a metal oxide semiconductor layer formed so as to cover an entirety of a surface of the metal oxide layer; and a source/drain electrode formed on the metal oxide semiconductor layer, wherein the thin-film transistor further comprises an oxygen depletion layer disposed in an area of the metal oxide semiconductor layer adjacent to the metal oxide layer, wherein the metal oxide semiconductor layer is obtained by crystallizing an amorphous metal oxide semiconductor layer under heat-treatment.

### CROSS-REFERENCE TO RELATED APPLICATIONS

This application claims the benefit under 35 USC § 119(a) of Korean Patent Application No. 10-2022-0097845 filed on Aug. 5, 2022 in the Korean Intellectual Property Office, the entire disclosure of which is incorporated herein by reference for all purposes.

### BACKGROUND

### Field

The present disclosure relates to a thin-film transistor applicable as an electronic element of a display, a memory, a circuit, and a method for manufacturing the same.

### Description of Related Art

An early display device was based on amorphous silicon material and was used in an LCD industry. The amorphous silicon material has low charge mobility. However, high charge mobility is required as resolution of the display device increases. Thus, a polycrystalline silicon material has been developed. The polycrystalline silicon material has disadvantages such as a complicated process, low yield, and high process temperature. Thus, in recent years, semiconductor material research has been conducted using a metal oxide inorganic material. An amorphous metal oxide inorganic material is being developed and researched due to advantages thereof such as high transparency, low-cost and large-area possibility, and excellent mobility. Nevertheless, the amorphous metal oxide inorganic material has limitation in terms of operation stability at high voltage, and insufficient mobility to be used for a next-generation high-resolution display. Thus, further research thereon is still needed. A semiconductor device with high charge mobility, large-area possibility, and operational stability is required in order to be used in the next-generation high-resolution display.

A metal oxide semiconductor as a semiconductor material that may replace the silicon material is being researched recently and is being applied to mass production. However, a conventional metal oxide thin-film element has low cost and insulating properties but has low mobility compared to a silicon thin-film element. A single crystal silicon has the mobility in a range of about 300 cm²/Vs. A low temperature polysilicon has the mobility in a range of about 100 cm²/Vs. However, the metal oxide has a low mobility in a range of 10 to 20 cm²/Vs. Additional improvement on the metal oxide is required such that the metal oxide is applicable to a large-area, high refresh rate and ultra-high resolution display in which fast response is required.

### SUMMARY

This Summary is provided to introduce a selection of concepts in a simplified form that are further described below in the Detailed Description. This Summary is not intended to identify all key features or essential features of the claimed subject matter, nor is it intended to be used alone as an aid in determining the scope of the claimed subject matter.

One purpose of the present disclosure is to provide a thin-film transistor including a crystalline metal oxide semiconductor with improved mobility and a method for manufacturing the same.

Another purpose of the present disclosure is to secure semiconductor manufacturing core technology in which a thin-film transistor manufactured via a method for manufacturing the present disclosure is applied not only to a high-resolution large-area display device but also to a conventional commercialized metal oxide based electronic element such as a photoelectric element, a memory element, a sensor, etc.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims and combinations thereof.

A first aspect of the present disclosure provides a method for manufacturing a thin-film transistor, the method comprising: a first step of forming a gate insulating film on a substrate, wherein the substrate serves as a gate electrode; a second step of forming a metal layer on the gate insulating film; a third step of forming an amorphous metal oxide semiconductor layer so as to cover an entirety of a surface of the metal layer to obtain a structure including the metal layer and the amorphous metal oxide semiconductor layer formed thereon; a fourth step of heat-treating the structure; and a fifth step of depositing a source/drain electrode layer on the heat-treated structure, wherein during the fourth step, a metal oxide layer is formed between the amorphous metal oxide semiconductor layer and the metal layer, the amorphous metal oxide semiconductor layer is crystallized, and an oxygen depletion area is formed in an area of the amorphous metal semiconductor layer adjacent to the metal layer or the metal oxide layer.

In some implementations of the first aspect, the metal layer is made of one selected from a group consisting of Al, Cr, Mo, Ag, Ta and Ti, or an alloy of at least two thereof.

In some implementations of the first aspect, the metal oxide layer is made of an oxide of a metal constituting the metal layer.

In some implementations of the first aspect, the amorphous metal oxide semiconductor is made of one selected from a group consisting of ZTO, IZTO, IGZTO, ZnO, IGZO, IZO, ITO, GZO, GZTO, ISZO and ISZTO.

In some implementations of the first aspect, the heat-treatment is performed at a temperature in a range of 100 to 1000° C.

In some implementations of the first aspect, a ratio of a width of the metal layer to a width of an exposed portion of a surface of the amorphous metal oxide layer not covered with the source/drain electrode layer is in a range of 0.5 inclusive to 1 exclusive.

A second aspect of the present disclosure provides a method for manufacturing a thin-film transistor, the method comprising: a first step of forming a gate electrode on a substrate and then forming a gate insulating film on the gate electrode; a second step of forming a metal layer on the gate insulating film; a third step of forming an amorphous metal oxide semiconductor layer so as to cover an entirety of a surface of the metal layer to obtain a structure including the metal layer and the amorphous metal oxide semiconductor layer formed thereon; a fourth step of heat-treating the structure; and a fifth step of depositing a source/drain electrode layer on the heat-treated structure, wherein during the fourth step, a metal oxide layer is formed between the amorphous metal oxide semiconductor layer and the metal layer, the amorphous metal oxide semiconductor layer is crystallized, and an oxygen depletion area is formed in an area of the amorphous metal semiconductor layer adjacent to the metal layer or the metal oxide layer.

In some implementations of the second aspect, the metal layer is made of one selected from a group consisting of Al, Cr, Mo, Ag, Ta and Ti, or an alloy of at least two thereof.

In some implementations of the second aspect, the metal oxide layer is made of an oxide of a metal constituting the metal layer.

In some implementations of the second aspect, the amorphous metal oxide semiconductor is made of one selected from a group consisting of ZTO, IZTO, IGZTO, ZnO, IGZO, IZO, ITO, GZO, GZTO, ISZO and ISZTO.

In some implementations of the second aspect, the heat-treatment is performed at a temperature in a range of 100 to 1000° C.

In some implementations of the second aspect, a ratio of a width of the metal layer to a width of an exposed portion of a surface of the amorphous metal oxide layer not covered with the source/drain electrode layer is in a range of 0.5 inclusive to 1 exclusive.

A third aspect of the present disclosure provides a thin-film transistor manufactured by the method of the first aspect, wherein the thin-film transistor includes: the substrate serving as a gate electrode; the gate insulating film formed on the substrate; the metal layer formed on the gate insulating film; the metal oxide layer formed on the metal layer and covering an entirety of a surface of the metal layer; a metal oxide semiconductor layer formed so as to cover an entirety of a surface of the metal oxide layer; and the source/drain electrode formed on the metal oxide semiconductor layer, wherein the thin-film transistor further comprises an oxygen depletion layer disposed in an area of the metal oxide semiconductor layer adjacent to the metal oxide layer.

In some implementations of the third aspect, the metal oxide semiconductor layer is obtained by crystallizing the amorphous metal oxide semiconductor layer under the heat-treatment.

A fourth aspect of the present disclosure provides a thin-film transistor manufactured by the method of the second aspect, wherein the thin-film transistor includes: the substrate; the gate electrode formed on the substrate; the gate insulating film formed on the gate electrode; the metal layer formed on the gate insulating film; the metal oxide layer formed on the metal layer and covering an entirety of a surface of the metal layer; a metal oxide semiconductor layer formed so as to cover an entirety of a surface of the metal oxide layer; and the source/drain electrode formed on the metal oxide semiconductor layer, wherein the thin-film transistor further comprises an oxygen depletion layer disposed in an area of the metal oxide semiconductor layer adjacent to the metal oxide layer.

In some implementations of the fourth aspect, the metal oxide semiconductor layer is obtained by crystallizing the amorphous metal oxide semiconductor layer under the heat-treatment.

According to the present disclosure, a high-mobility crystalline metal oxide-based element applicable to implementation of ultra-high resolution and large-area display and core technology for manufacturing the same may be provided. A next-generation display using the high-mobility crystalline metal oxide semiconductors may be realized such that technological competitiveness may be achieved. The high-mobility crystalline metal oxide-based element may be applied not only to the display and but also to an electronic device such as a memory and a circuit using the electrical properties of various metal oxides.

In addition to the above effects, specific effects of the present disclosure are described together while describing specific details for carrying out the present disclosure.

Effects of the present disclosure are not limited to the effects mentioned above, and other effects not mentioned will be clearly understood by those skilled in the art from the descriptions below.

### BRIEF DESCRIPTION OF DRAWINGS

FIG. 1 is a flow chart of a method for manufacturing a thin-film transistor of the present

disclosure.

FIG. 2 is a diagram showing a thin-film transistor according to the present disclosure and a method for manufacturing the same.

FIG. 3A shows a three-dimensional structure of a thin-film transistor manufactured according to one embodiment of the present disclosure, and FIG. 3B is a diagram showing a cross-sectional structure and a microscope image thereof. L_{bar} represents a width of a metal layer, and L_{ch} represents a spacing between source/drain electrodes (a length of a channel area).

FIG. 4 is a TEM (transmission electron microscopy) image showing a cross-section of a thin-film transistor manufactured according to one embodiment of the present disclosure.

FIG. 5A shows EDS (Energy Dispersive Spectroscopy) of TEM, and FIG. 5B is a graph showing a result of analyzing elemental components of a thin-film transistor manufactured according to one embodiment of the present disclosure via line scanning.

FIG. 6A and 6B are graphs showing characteristics of a thin-film transistor when an Al metal layer with a width L_{bar} of each of 0, 15, 30, and 45 μm is applied to the thin-film transistor element with a channel length L_{ch} of 50 μm. FIG. 6A shows a graph showing a drain current based on a gate voltage. FIG. 6B is a graph showing a field effect mobility based on the gate voltage.

FIG. 7A and 7D are graphs showing characteristics of a thin-film transistor when an Al metal layer with a width L_{bar} of each of 0, 15, 30, and 45 μm is applied to the thin-film transistor element with a channel length L_{ch} of 50 μm. FIG. 7A shows the field effect mobility based on the width L_{bar}. FIG. 7B shows an on/off current ratio based on the width L_{bar}. FIG. 7C shows a threshold voltage Vₜₕ based on the width L_{bar}. FIG. 7D shows a subthreshold slope based on the width L_{bar}.

FIG. 8 is a graph showing activation energy of a thin-film transistor based on a width of a metal layer.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for describing embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various embodiments of the present disclosure may be partially or entirely combined with each other, and may be technically associated with each other or operate with each other. The embodiments may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for describing embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

As used herein, ‘amorphous’ means a state in which atoms in a material are randomly arranged without having a specific periodicity.

As used herein, ‘crystallization’ means change from a state in which atoms are randomly arranged to a state in which the atoms have a specific arrangement structure.

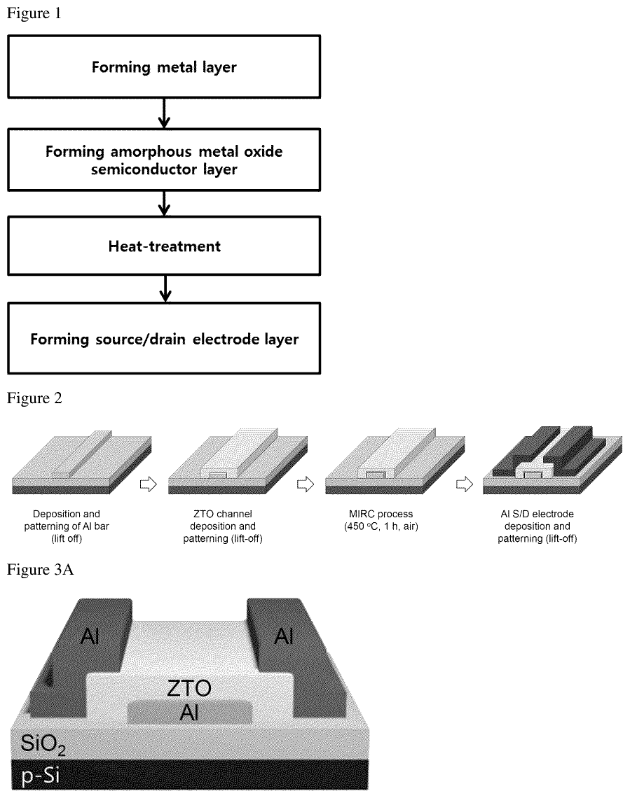

FIGS. 1 and 2 are diagrams for illustrating a thin-film transistor according to the present disclosure and a method for manufacturing the same.

Referring to FIGS. 1 and 2, a method for manufacturing the thin-film transistor according to the present disclosure includes a first step of forming a gate electrode on a substrate and forming a gate insulating film on the gate electrode, a second step of forming a metal layer on the gate insulating film, a third step of forming an amorphous metal oxide semiconductor layer so as to entirely cover a surface of the metal layer to manufacturing a structure, a fourth step of heat-treating the structure, and a fifth step of depositing a source/drain electrode layer on the heat-treated structure.

In this case, it is common that in the first step, the gate electrode is formed on the substrate, and the gate insulating film is formed on the gate electrode. However, when the substrate itself serves as the gate electrode (for example, when p-type Si is used as both the substrate and the gate electrode as shown in FIG. 2), the gate insulating film may be directly formed on the substrate. Throughout the present disclosure, the first step may be equally applied to the case where the substrate acts as the gate electrode and the case where the substrate does not act as the gate electrode. However, the former and the latter are separately claimed in the claims.

The substrate may include silicon (Si). However, the present disclosure is not limited thereto. The substrate may include glass or polymer. The substrate may be a p-type substrate containing p-type impurity ions or an n-type substrate containing n-type impurity ions. In the thin-film transistor of one embodiment of the present disclosure, the substrate may be a p-type Si substrate.

The gate electrode may be made of any one metal selected from the group consisting of Al, Cr, Mo, Ta, and Ti or an alloy of at least two thereof. However, the present disclosure is not limited thereto.

The gate insulating film may be made of at least one of SiO₂, Si₃N₄, Al₂O₃, HfO₂, or ZrO₂. In one embodiment, the gate insulating film may be made of SiO₂. A thickness of the gate insulating film may be in a range of about 1 to 1000 nm.

In the first step, the formation of the gate insulating film may be performed in a thermal oxidation scheme. The formation of a stable gate insulating film is very important in the thin-film transistor of the present disclosure. Therefore, in one embodiment of the present disclosure, a SiO₂ gate insulating film may be formed on the substrate in the thermal oxidation manner.

The metal layer may be made of any one metal selected from the group consisting of Al, Cr, Mo, Al, Ag, Ta, and Ti. However, the present disclosure is not necessarily limited thereto. For example, in one embodiment, the metal layer may be made of Al. A thickness of the metal layer may be in a range of about 1 to 50 nm. Preferably, the thickness of the metal layer may be in a range of about 1 to 15 nm.

In one embodiment, the metal layer may be a patterned metal layer. The patterned metal layer may increase integration of the thin-film transistor. Further, characteristics of the thin-film transistor according to the present disclosure may be controlled based on a width L_{bar} of the patterned metal layer. Details related thereto will be described in detail with reference to experimental examples below.

The formation of the metal layer in the second step may be performed in a manner selected from sputtering, E-beam evaporation, thermal evaporation, L-MBE (Laser Molecular Beam Epitaxy), pulsed laser deposition (PLD), Metal-Organic Chemical Vapor Deposition, (MOCVD), Hydride Vapor Phase Epitaxy (HVPE), and the like. Preferably, the formation of the metal layer may be performed in the thermal evaporation manner. After depositing the metal layer in the above manner, an additional patterning step may be performed thereon. For example, the patterning may be performed using photolithography.

The amorphous metal oxide semiconductor layer may be made of any one material selected from ZTO, IZTO, IGZTO, ZnO, IGZO, IZO, ITO, GZO, GZTO, ISZO, and ISZTO. For example, the amorphous metal oxide semiconductor may be made of ZTO.

The formation of the amorphous metal oxide semiconductor layer in the third step may be performed in a vacuum deposition manner such as sputtering or ALD (atomic layer deposition), a spin coating manner, or an inkjet manner. In one embodiment, the amorphous metal oxide semiconductor layer may be formed using RF sputtering. The amorphous metal oxide semiconductor layer may be formed to cover an entirety of an exposed surface of the metal layer. When the metal layer has been patterned, the amorphous metal oxide semiconductor layer may be formed in the same pattern as the pattern of the metal layer. In this regard, the patterning of the amorphous metal oxide semiconductor layer may be performed using photolithography.

The heat-treatment in the fourth step may be performed at a temperature of about 100 to 1000° C., preferably at a temperature of about 200 to 800° C., more preferably at a temperature of about 400 to 600° C. The heat-treatment time or scheme is not particularly limited in the present disclosure, and may be selected in consideration of a purpose desired by the experimenter.

During the fourth step, the metal layer in contact with the amorphous metal oxide semiconductor layer may absorb oxygen from the amorphous metal oxide semiconductor layer to form a metal oxide layer at an interface therebetween. That is, the metal oxide layer is made of an oxidized product of the metal of the metal layer. In this regard, an oxygen depletion area or an oxygen depletion layer may be generated in an area of the amorphous metal semiconductor layer adjacent to the metal layer or the metal oxide layer. Simultaneously with this process, the amorphous metal oxide semiconductor layer may be crystallized.

In summary, according to the present disclosure, after the fourth step has been performed, the structure including the metal layer and the amorphous metal oxide semiconductor layer formed on the metal layer may be converted into a structure including the metal layer, the metal oxide layer formed on the metal layer, and the crystallized crystalline metal oxide semiconductor layer formed on the metal oxide layer. In addition, the crystalline metal oxide semiconductor layer may include the oxygen depletion layer in an area thereof adjacent to the metal oxide layer.

The source/drain electrode may be made of a metal, for example, any one metal selected from the group consisting of Al, Ag, Au, Cr, Mo, Al, Ag, Ta, and Ti.

In the fifth step, the source/drain electrode layer may be formed in a thermal evaporation scheme. The source/drain electrode layer may be formed on the crystalline metal oxide semiconductor layer and may not entirely cover the surface of the crystalline metal oxide semiconductor layer, that is, may cover only a portion of the surface of the crystalline metal oxide semiconductor layer.

After the fifth step, the exposed portion of the surface of the crystalline oxide semiconductor layer not covered with the source/drain electrode layer may be defined as a channel area or a channel layer. In accordance with the present disclosure, the characteristics of the thin-film transistor according to the present disclosure may be controlled based on a width L_{ch} of the channel area, that is, a distance between the source electrode and the drain electrode.

In an embodiment, a ratio L_{bar}/L_{ch} of a width L_{bar} of the metal layer and a width L_{ch} of the exposed portion of the surface of the amorphous metal oxide layer not covered with the source and drain may be smaller than 1. In the thin-film transistor of the present disclosure, the electrical characteristics of the thin-film transistor may change based on the ratio of L_{bar}/L_{ch}. In general, as the ratio L_{bar}/L_{ch} is closer to 1, the carrier mobility may be greater. However, when the underlying metal layer and the source/drain electrodes on top of the channel overlap each other at both opposing sides, the improvement in the mobility characteristics may deteriorate. Thus, in accordance with the present disclosure, the ratio L_{bar}/L_{ch} may be in a range of 0.5 inclusive to 1 exclusive or in a range of 0.8 inclusive to 1 exclusive.

The thin-film transistor according to the present disclosure is manufactured according to the method for manufacturing the thin-film transistor according to the present disclosure, and includes the substrate, the gate insulating film formed on the substrate, the metal layer formed on the gate insulating film, a metal oxide layer formed on the metal layer so as to cover the entirety of the surface of the metal layer, the metal oxide semiconductor layer formed to cover the entirety of the surface of the metal oxide layer, and the source/drain electrode formed on the metal oxide semiconductor layer, wherein the thin-film transistor further includes an oxygen depletion layer in an area of the metal oxide semiconductor layer adjacent to the metal oxide layer.

The thin-film transistor according to the present disclosure is characterized in that the metal oxide layer, that is, the insulator layer is formed between the metal layer and the metal oxide semiconductor layer. This may have a positive effect on additional charge accumulation and charge transport of the metal oxide semiconductor layer, compared to a conventional transistor having the metal layer on top of the metal oxide semiconductor layer.

The oxygen depletion layer may improve charge concentration and mobility. This may be identified based on change in activation energy (EA) of the transistor element after heat-treatment. This will be described in detail based on following experimental example.

The metal oxide semiconductor layer may be a crystalline metal oxide semiconductor layer, and may be obtained by crystallizing the amorphous metal oxide semiconductor layer under the heat-treatment.

Hereinafter, the thin-film transistor according to the present disclosure and the method for manufacturing the same will be described in more detail based on specific examples and comparative examples. However, the examples of the present disclosure are merely embodiments of the present disclosure, and the scope of the present disclosure is not limited to the following examples.

### EXAMPLE

A SiO₂ film with a thickness of about 200 nm was formed on a p-type silicon substrate used as the substrate and the electrode. The film was used as a gate insulating film. An aluminum (Al) metal layer was formed on top of the SiO₂ gate insulating film in the thermal evaporation scheme, and the patterning was performed thereon using photolithography. Then, an amorphous ZTO (zinc tin oxide) metal oxide semiconductor layer was formed on top of the patterned metal layer in the RF sputtering manner. In this regard, a content ratio Zn:Sn of the ZTO target material was 7:3. The metal oxide semiconductor layer was formed and then was patterned using photolithography. Then, the heat-treatment was performed on the resulting structure for 1 hour at a temperature of 450° C. in air. The heat treatment was carried out using a hot plate. During the heat-treatment process, the Al layer in contact with the ZTO layer absorbed oxygen in the adjacent ZTO layer to produce aluminum oxide Al₂O₃ at the interface therebetween, and at the same time to crystallize the amorphous ZTO layer. Further, the oxygen depletion layer was formed in an area of the ZTO layer adjacent to the Al layer. Finally, the source/drain electrode was formed thereon. The source/drain electrode was made of Al and was formed in a thermal evaporation scheme. Then, patterning was performed thereon using photolithography to manufacture the thin-film transistor according to one embodiment of the present disclosure.

### Experimental Example

### \textcircled{1} Structural Analysis

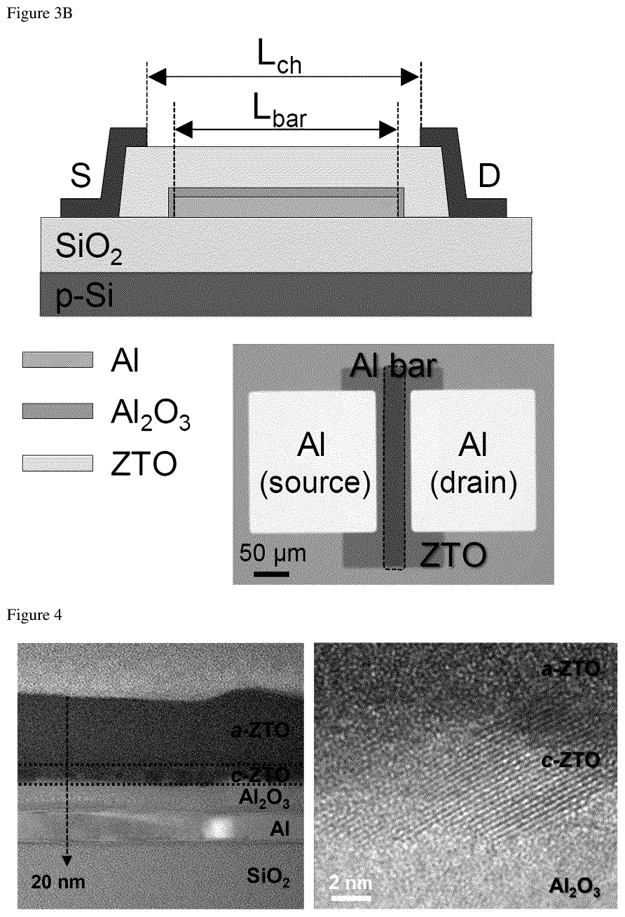

FIG. 3A shows a three-dimensional structure of a thin-film transistor manufactured according to one embodiment of the present disclosure, and FIG. 3B is a diagram showing a cross-sectional structure and a microscope image thereof. L_{bar} represents a width of a metal layer, and L_{ch} represents a spacing between source/drain electrodes (a length of a channel area).

Referring to FIG. 3A, in the thin-film transistor of the present disclosure, the aluminum oxide (Al₂O₃) layer was formed between the Al layer and the ZTO layer under the heat-treatment. The oxygen-deficient layer (not shown) was formed in an area in the ZTO layer adjacent to the Al layer. Referring to FIG. 3B, the electrical characteristics of the thin-film transistor according to the present disclosure may be controlled based on=the ratio L_{bar}/L_{ch}. As the ratio of L_{bar}/L_{ch} is closer to 1, the carrier mobility of the thin-film transistor may be increased. However, when L_{bar}<L_{ch}, the improvement of the mobility characteristics of the thin-film transistor may be reduced.

### \textcircled{1} Cross-Sectional Analysis

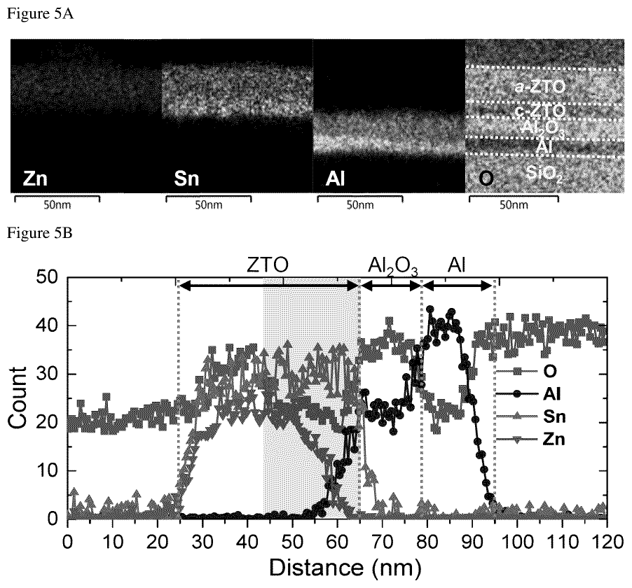

FIG. 4 is a TEM (transmission electron microscopy) image showing a cross-section of a thin-film transistor manufactured according to one embodiment of the present disclosure.

Referring to FIG. 4, it may be identified that the aluminum oxide (Al₂O₃) layer and the crystallized ZTO layer (c-ZTO) are formed between the Al layer and the ZTO layer (a-ZTO).

### \textcircled{3} Elemental Analysis

FIG. 5A shows EDS (Energy Dispersive Spectroscopy) of TEM, and FIG. 5B is a graph showing a result of analyzing elemental components of a thin-film transistor manufactured according to one embodiment of the present disclosure via line scanning.

Referring to FIG. 5A and FIG. 5B, it may be identified that the oxygen depletion layer is present in an area in the crystallized ZTO layer (c-ZTO layer) adjacent to the aluminum oxide (Al₂O₃) layer. It is known that the presence of the oxygen depletion layer in the metal oxide semiconductor layer may increase the electron concentration and increase the carrier mobility. Therefore, the thin-film transistor according to the present disclosure may include the oxygen depletion layer in the metal oxide semiconductor layer to provide high carrier mobility characteristics.

\textcircled{4} Thin-Film Transistor Characteristics

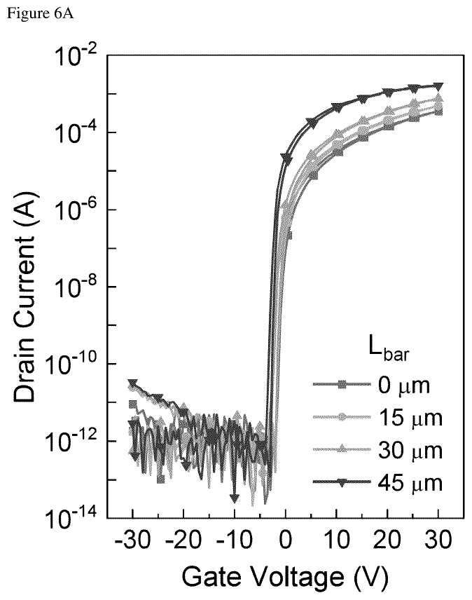

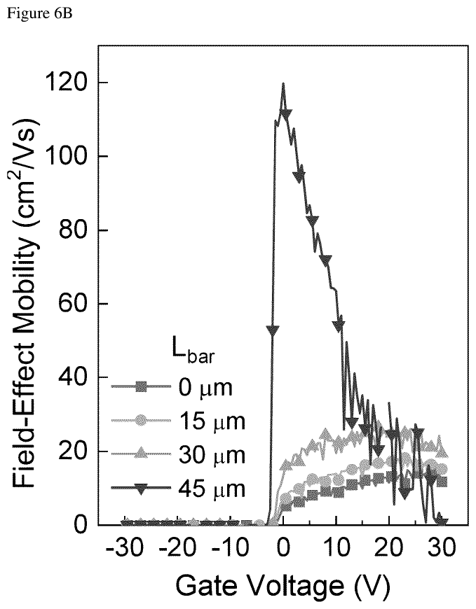

FIG. 6 are graphs showing characteristics of a thin-film transistor when an Al metal layer with a width L_{bar} of each of 0, 15, 30, and 45 μm is applied to the thin-film transistor element with a channel length L_{ch} of 50 μm. FIG. 6A shows a graph showing a drain current based on a gate voltage. FIG. 6B is a graph showing a field effect mobility based on the gate voltage.

Referring to FIG. 6A, it is identified that the drain current increases when the size of L_{bar} increases from 0 to 45 μm. Referring to FIG. 6B, it is identified that the field effect mobility also tends to increase as the size of L_{bar} increases. In particular, when the L_{bar} is 45 μm, the field effect mobility is greater than or equal to 100 cm²/Vs.

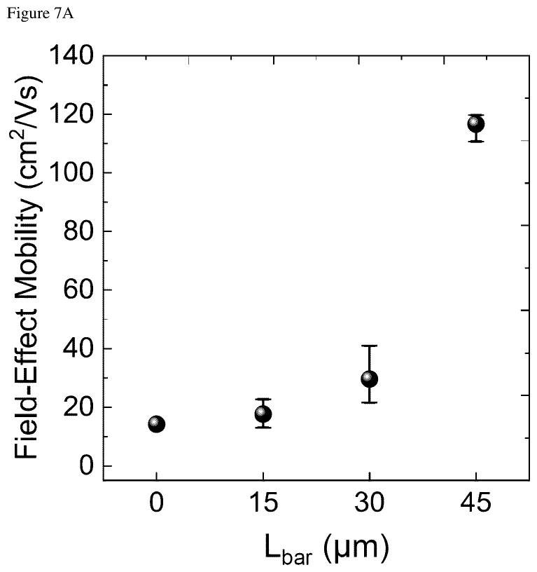

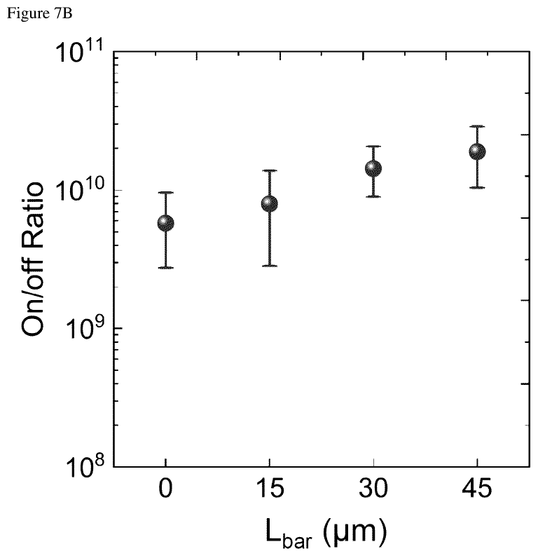

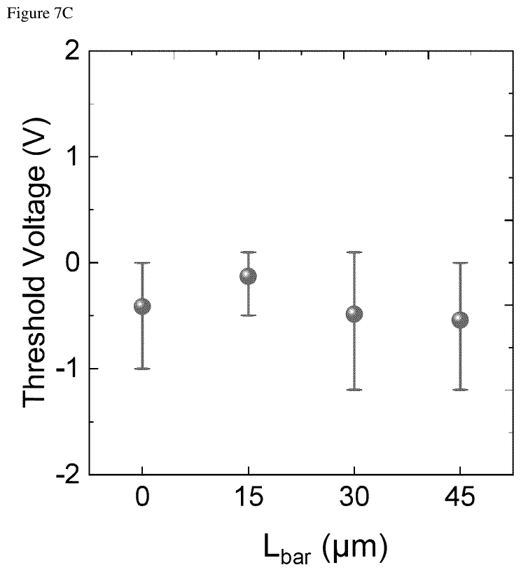

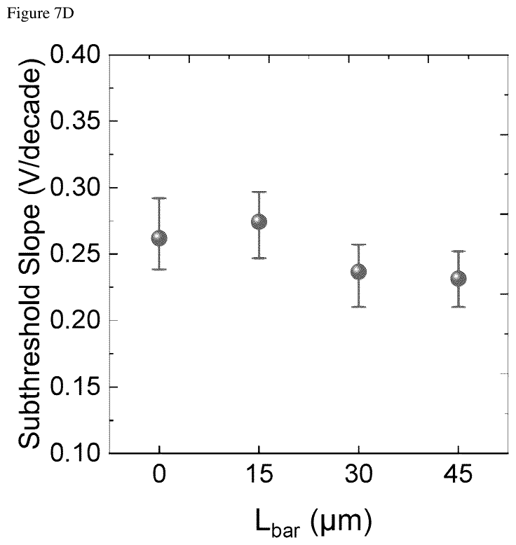

FIG. 7 are graphs showing characteristics of a thin-film transistor when an Al metal layer with a width L_{bar} of each of 0, 15, 30, and 45 μm is applied to the thin-film transistor element with a channel length L_{ch} of 50 μm. FIG. 7A shows the field effect mobility based on the width L_{bar}. FIG. 7B shows an on/off current ratio based on the width L_{bar}. FIG. 7C shows a threshold voltage Vₜₕ based on the width L_{bar}. FIG. 7D shows a subthreshold slope based on the width L_{bar}.

Referring to FIG. 7A, as the size of L_{bar} increases, the field effect mobility tends to increase. To the contrary, referring to FIGS. 7B, 7C, and 7D, each of the on/off current ratio, the threshold voltage, and the subthreshold slope is similar to that when the Al metal layer is absent.

### \textcircled{5} Activation Energy Analysis

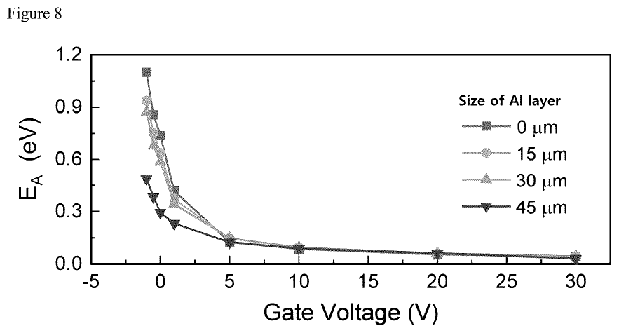

FIG. 8 is a graph showing the activation energy of the thin-film transistor based on the width of the metal layer.

Referring to FIG. 8, it is identified that the activation energy is reduced as the width of the metal layer increases. In particular, the activation energy decreases as the width of the metal layer is closer to the channel length. The decrease in the activation energy may be due to the presence of the oxygen depletion layer or the crystallized layer.

Although the embodiments of the present disclosure have been described with reference to the accompanying drawings, the present disclosure is not limited to the above embodiments and may be implemented in various different forms. Those of ordinary skill in the technical field to which the present disclosure belongs will be able to understand that the present disclosure may be implemented in other specific forms without changing the technical idea or essential characteristics of the present disclosure. Therefore, it should be understood that the embodiments as described above are not restrictive but illustrative in all respects.

What is claimed is:

1. A method for manufacturing a thin-film transistor, the method comprising:
a first step of forming a gate insulating film on a substrate, wherein the substrate serves as a gate electrode;
a second step of forming a metal layer on the gate insulating film;
a third step of forming an amorphous metal oxide semiconductor layer so as to cover an entirety of a surface of the metal layer to obtain a structure including the metal layer and the amorphous metal oxide semiconductor layer formed thereon;
a fourth step of heat-treating the structure; and
a fifth step of depositing a source/drain electrode layer on the heat-treated structure,
wherein during the fourth step, a metal oxide layer is formed between the amorphous metal oxide semiconductor layer and the metal layer, the amorphous metal oxide semiconductor layer is crystallized, and an oxygen depletion area is formed in an area of the amorphous metal semiconductor layer adjacent to the metal layer or the metal oxide layer.

2. The method of claim 1, wherein the metal layer is made of one selected from a group consisting of Al, Cr, Mo, Ag, Ta and Ti, or an alloy of at least two thereof

3. The method of claim 2, wherein the metal oxide layer is made of an oxide of a metal constituting the metal layer.

4. The method of claim 1, wherein the amorphous metal oxide semiconductor is made of one selected from a group consisting of ZTO, IZTO, IGZTO, ZnO, IGZO, IZO, ITO, GZO, GZTO, ISZO and ISZTO.

5. The method of claim 1, wherein the heat-treatment is performed at a temperature in a range of 100 to 1000° C.

6. The method of claim 1, wherein a ratio of a width of the metal layer to a width of an exposed portion of a surface of the amorphous metal oxide layer not covered with the source/drain electrode layer is in a range of 0.5 inclusive to 1 exclusive.

7. A method for manufacturing a thin-film transistor, the method comprising:
a first step of forming a gate electrode on a substrate and then forming a gate insulating film on the gate electrode;
a second step of forming a metal layer on the gate insulating film;
a third step of forming an amorphous metal oxide semiconductor layer so as to cover an entirety of a surface of the metal layer to obtain a structure including the metal layer and the amorphous metal oxide semiconductor layer formed thereon;
a fourth step of heat-treating the structure; and
a fifth step of depositing a source/drain electrode layer on the heat-treated structure,
wherein during the fourth step, a metal oxide layer is formed between the amorphous metal oxide semiconductor layer and the metal layer, the amorphous metal oxide semiconductor layer is crystallized, and an oxygen depletion area is formed in an area of the amorphous metal semiconductor layer adjacent to the metal layer or the metal oxide layer.

8. The method of claim 7, wherein the metal layer is made of one selected from a group consisting of Al, Cr, Mo, Ag, Ta and Ti, or an alloy of at least two thereof.

9. The method of claim 8, wherein the metal oxide layer is made of an oxide of a metal constituting the metal layer.

10. The method of claim 7, wherein the amorphous metal oxide semiconductor is made of one selected from a group consisting of ZTO, IZTO, IGZTO, ZnO, IGZO, IZO, ITO, GZO, GZTO, ISZO and ISZTO.

11. The method of claim 7, wherein the heat-treatment is performed at a temperature in a range of 100 to 1000° C.

12. The method of claim 7, wherein a ratio of a width of the metal layer to a width of an exposed portion of a surface of the amorphous metal oxide layer not covered with the source/drain electrode layer is in a range of 0.5 inclusive to 1 exclusive.

13. A thin-film transistor manufactured by the method of claim 1, wherein the thin-film transistor includes:
the substrate serving as a gate electrode;
the gate insulating film formed on the substrate;
the metal layer formed on the gate insulating film;
the metal oxide layer formed on the metal layer and covering an entirety of a surface of the metal layer;
a metal oxide semiconductor layer formed so as to cover an entirety of a surface of the metal oxide layer; and
the source/drain electrode formed on the metal oxide semiconductor layer,
wherein the thin-film transistor further comprises an oxygen depletion layer disposed in an area of the metal oxide semiconductor layer adjacent to the metal oxide layer.

14. The thin-film transistor of claim 13, wherein the metal oxide semiconductor layer is obtained by crystallizing the amorphous metal oxide semiconductor layer under the heat-treatment.

15. A thin-film transistor manufactured by the method of claim 7, wherein the thin-film transistor includes:
the substrate;
the gate electrode formed on the substrate;
the gate insulating film formed on the gate electrode;
the metal layer formed on the gate insulating film;
the metal oxide layer formed on the metal layer and covering an entirety of a surface of the metal layer;
a metal oxide semiconductor layer formed so as to cover an entirety of a surface of the metal oxide layer; and
the source/drain electrode formed on the metal oxide semiconductor layer,
wherein the thin-film transistor further comprises an oxygen depletion layer disposed in an area of the metal oxide semiconductor layer adjacent to the metal oxide layer.

16. The thin-film transistor of claim 15, wherein the metal oxide semiconductor layer is obtained by crystallizing the amorphous metal oxide semiconductor layer under the heat-treatment.
